(19) United States
(12) Patent Application Publication
(10) Pub. No.: US 2022/0181479 A1
(43) Pub. Date: Jun. 9, 2022

(54) WIDE BANDGAP SEMICONDUCTOR DEVICE WITH A SELF-ALIGNED CHANNEL AND INTEGRATION SCHEMES

(71) Applicant: GLOBALFOUNDRIES Singapore Pte. Ltd., Singapore (SG)

(72) Inventors: CHOR SHU CHENG, Singapore (SG); HANDOKO LINEWIH, Singapore (SG); SIOW LEE CHWA, Singapore (SG)

(21) Appl. No.: 17/115,724

(22) Filed: Dec. 8, 2020

(51) Int. Cl. H01L 29/78; H01L 29/16; H01L 29/10; H01L 29/417; H01L 29/423; H01L 29/66

(52) U.S. Cl. CPC H01L 29/7802; H01L 29/1608; H01L 29/66068; H01L 29/41741; H01L 29/42368; H01L 29/1095

(57) ABSTRACT

A semiconductor device is provided. The semiconductor device comprises a substrate having a wide bandgap semiconductor material and an epitaxial layer arranged over a first surface of the substrate. A source region having a first conductivity type may be arranged in the epitaxial layer. A well region having a second conductivity type may be laterally adjacent to the source region. The first conductivity type may be different from the second conductivity type. A gate dielectric layer may be arranged over the well region. A field dielectric layer may be arranged over the epitaxial layer adjacent to the well region.

### FIELD OF THE INVENTION

The disclosed embodiments relate generally to wide bandgap semiconductor devices, and more particularly, to wide bandgap semiconductor devices with a self-aligned channel for a low resistance and high breakdown voltage.

### BACKGROUND

Wide bandgap semiconductor materials such as silicon carbide (SiC) enable devices to operate at higher voltages, frequencies and temperatures than conventional semiconductor materials such as silicon (Si) and gallium arsenide (GaAs). For example, silicon carbide has the potential to replace silicon for applications such as power metal oxide semiconductor field effect transistor (MOSFET). Silicon carbide power MOSFET has significant advantages over silicon devices, including faster switching speed, lower specific on-resistance and lower power losses.

During device operation, a channel may form in a well region under a gate electrode adjacent to a source. One of the challenges for fabrication of silicon carbide power MOSFET is providing a consistent channel length. Mask misalignment during the source and well region formation will result in an inconsistent channel length thereby increasing the on-resistance and affecting device performance. Thus, there is a need to overcome the challenges mentioned above.

### SUMMARY

In an aspect of the present disclosure, a structure is provided. The structure comprises a substrate having a wide bandgap semiconductor material and an epitaxial layer arranged over a first surface of the substrate. A source region having a first conductivity type may be arranged in the epitaxial layer. A well region having a second conductivity type may be laterally adjacent to the source region. The second conductivity type may be different from the first conductivity type. A gate dielectric layer may be arranged over the well region. A field dielectric layer may be arranged over the epitaxial layer adjacent to the well region.

In another aspect of the present disclosure, a structure is provided. The structure comprises a substrate having a wide bandgap semiconductor material. An epitaxial layer may be arranged over a first surface of the substrate, whereby the epitaxial layer includes the same wide bandgap semiconductor material as the substrate. A source region having a first conductivity type may be arranged in an upper portion of the epitaxial layer. A well region having a second conductivity type may be laterally adjacent to the source region. The second conductivity type may be different from the first conductivity type. A gate dielectric layer may be arranged over the well region. A field dielectric layer may be arranged over the epitaxial layer adjacent to the well region.

In yet another aspect of the present disclosure, a method of fabricating a semiconductor structure is provided. The method comprises providing a substrate having a wide bandgap semiconductor material. An epitaxial layer may be provided over a first surface of the substrate. A source region having a first conductivity type may be provided in the epitaxial layer. A well region having a second conductivity type may be provided laterally adjacent to the source region. The second conductivity type may be different from the first conductivity type. A field dielectric layer may be provided over the epitaxial layer adjacent to the well region. A gate dielectric layer may be provided over the well region.

Numerous advantages may be derived from the embodiments described below. The embodiments provide a semiconductor device with a self-aligned channel having a low on-resistance and a high breakdown voltage. The device has a consistent channel length and threshold voltage providing consistent device performance.

### BRIEF DESCRIPTION OF THE DRAWINGS

The disclosed embodiments will be better understood from a reading of the following detailed description, taken in conjunction with the accompanying drawings:

FIG. 1A is a top view of a semiconductor device array, according to an embodiment of the disclosure.

FIG. 1B is a cross-section view of the semiconductor device array shown in FIG. 1A taken along section line A-A′, according to an embodiment of the disclosure.

FIG. 1C is a cross-section view of the semiconductor device array shown in FIG. 1A taken along section line B-B′, according to an embodiment of the disclosure.

FIGS. 2 to 12 illustrate a process flow for fabricating a semiconductor device shown in FIG. 1B, according to an embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the devices. Additionally, elements in the drawings are not necessarily drawn to scale. For example, the dimensions of some of the elements in the drawings may be exaggerated relative to other elements to help improve understanding of embodiments of the devices. The same reference numerals in different drawings denote the same elements, while similar reference numerals may, but do not necessarily, denote similar elements.

### DETAILED DESCRIPTION

The following detailed description is exemplary in nature and is not intended to limit the devices or the application and uses of the devices. Furthermore, there is no intention to be bound by any theory presented in the preceding background of the devices or the following detailed description.

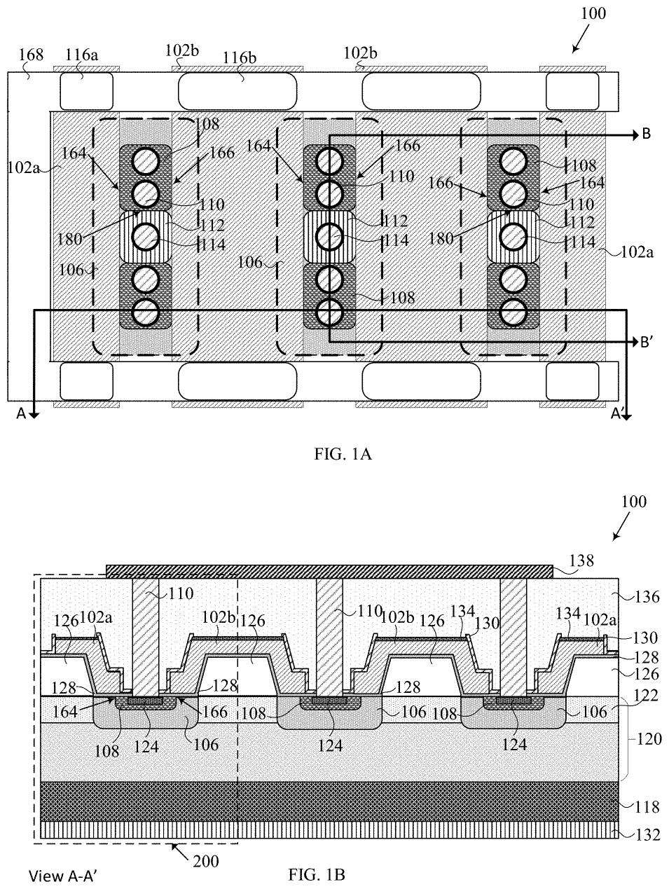

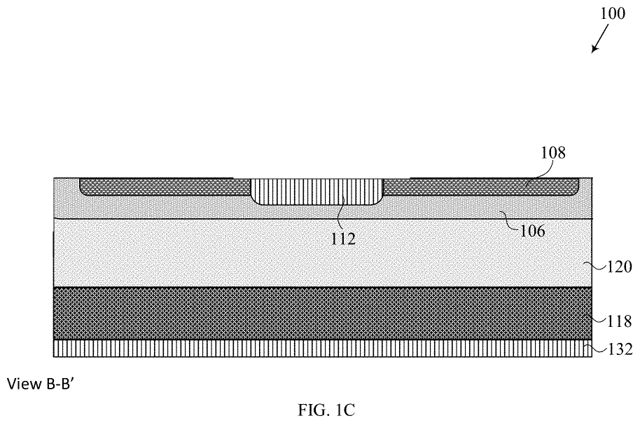

FIG. 1A is a top view of a semiconductor device array 100, according to an embodiment of the disclosure. Referring to FIG. 1A, a source region 108 having a first side 164 and a second side 166 opposite to the first side 164 may be provided. The source region 108 may have a first conductivity type. A well region 106 having a second conductivity type may be provided. The well region 106 may be laterally adjacent to the first side 164 and the second side 166 of the source region 108. The well region 106 is illustrated as a dashed outline. The first conductivity type may be different from the second conductivity type. In one embodiment, the first conductivity type may be n-type and the second conductivity type may be p-type. In one embodiment, a gate electrode 102a may be arranged over a portion of the well region 106 adjacent to the first 164 side of the source region 108 and a gate electrode 102b may be arranged over a portion of the well region 106 adjacent to the second side 166 of the source region 108. In another embodiment, a gate electrode 102b may be arranged over a portion of the well region 106 adjacent to the first side 164 of the source region 108 and the second side 166 of the source region 108 opposite to the first side 166. In one embodiment, a gate electrode 102a may be arranged over a portion of the well region 106 overlapping the first 164 side of the source region 108 and a gate electrode 102b may be arranged over a portion of the well region 106 overlapping the second side 166 of the source region 108. In another embodiment, a gate electrode 102b may be arranged over a portion of the well region 106 overlapping the first side 164 of the source region 108 and the second side 166 of the source region 108 opposite to the first side 166. Contact pillars 116a and 116b may connect the gate electrodes 102a and 102b, respectively, to a metallization layer 168. A well contact region 112 having a second conductivity type may be arranged in the well region 106. The well contact region 112 may be adjacent to the source region 108. In one embodiment, the well contact region 112 may be adjacent to a third side 180 of the source region 108, whereby the third side 180 may be between the first side 164 and the second side 166 of the source region 108. A first contact pillar 110 may be arranged over the source region 108 and a second contact pillar 114 may be arranged over the well contact region 112. A metallization layer may be arranged over the first 110 and second 114 contact pillars. For simplicity, the metallization layer over the first 110 and second 114 contact pillars is not shown in this top view. Although not shown, an interlayer dielectric (ILD) layer may be arranged over the source region 108, the well contact region 112, the well region 106 and the gate electrodes 102a and 102b.

FIG. 1B is a cross-section view of the semiconductor device array 100 shown in FIG. 1A taken along section line A-A′, according to an embodiment of the disclosure. Referring to FIG. 1B, a substrate 118 having a wide bandgap semiconductor material may be provided. In one embodiment, the wide bandgap semiconductor material may be silicon carbide (SiC). An epitaxial layer 120 may be arranged over a first surface of the substrate 118. The epitaxial layer 120 may include the same wide bandgap semiconductor material as the substrate 118. In one embodiment, the epitaxial layer 120 may have a first conductivity type. In one embodiment, an upper portion 122 of the epitaxial layer 120 may have a first conductivity type. The upper portion 122 of the epitaxial layer 120 may be formed by an ion implantation process. A source region 108 having a first conductivity type may be arranged in the epitaxial layer 120 in one embodiment and in the upper portion 122 of the epitaxial layer 120 in a preferred embodiment. A well region 106 having a second conductivity type may be adjacent to a first side of the source region 108 and a second side of the source region 108 opposite to the first side. In one embodiment, the well region 106 may surround the source region 108. The well region 106 may be arranged in the epitaxial layer 120 in one embodiment and in the upper portion 122 of the epitaxial layer 120 in a preferred embodiment. A field dielectric layer 126 may be arranged over the epitaxial layer 120 adjacent to the well region 106. A gate dielectric layer 128 may be arranged over the well region 106, whereby the gate dielectric layer 128 may be thinner than the field dielectric layer 126. The gate dielectric layer 128 may be arranged over the field dielectric layer 126. The gate dielectric layer 128 may be arranged over at least part of the source region 108. In one embodiment, the gate dielectric layer 128 may overlap the first side 164 of the source region 108 and the second side 166 of the source region 108 opposite to the first side 166. A gate electrode 102a and 102b may be arranged over the gate dielectric layer 128 and the field dielectric layer 126. A spacer structure 130 may be arranged over side surfaces of the gate electrode 102a and 102b. A silicide layer 134 may be arranged over a top surface of the gate electrode 102a and 102b. A silicide layer 124 may be arranged over the source region 108. An interlayer dielectric (ILD) layer 136 may be arranged over the source region 108, the gate electrode 102a and 102b, the field dielectric layer 126 and the epitaxial layer 120. A first contact pillar 110 may be arranged over the source region 108, whereby the first contact pillar 110 may be in the interlayer dielectric layer 136. A metallization layer 138 may be arranged over the interlayer dielectric layer 136 and the first contact pillar 110. A drain region 132 may be arranged over a second surface of the substrate 118, whereby the second surface of the substrate 118 may be opposite to the first surface and the epitaxial layer 120.

The term “wide bandgap semiconductor” may be a semiconductor material with bandgap energy in the range of 2 to 6 eV, at room temperature. A bandgap refers to a difference in energy between a valence band and a conduction band of a semiconductor that consists of a range of energy values forbidden to electrons in the semiconductor. A valence band is a band of electron orbitals that electrons can jump out of, moving into a conduction band when excited. The valence band is the outermost electron orbital of an atom of any specific material that electrons actually occupy. The conduction band is the band of electron orbitals that electrons can jump up into from the valence band when excited. When the electrons are in these orbitals, they have enough energy to move freely in the material. This movement of electrons creates an electric current.

Referring to FIG. 1B, a semiconductor device 200 is shown as part of the semiconductor device array 100. In one embodiment, the semiconductor device 200 may be a vertical drain transistor. The operating principle of the semiconductor device 200 will be described as follows. On application of a positive voltage on the gate electrode layers 102a and 102b in the state where a voltage is applied between the source region 108 and the drain region 132, an electron inversion layer is formed on surfaces of the well region 106 under the gate electrode layers 102a and 102b to form a channel region laterally adjacent to the source region 108. As a result, an electric current flows from the drain region 132 to the source region 108 through the substrate 118, the epitaxial layer 120 and the well region 106.

FIG. 1C is a cross-section view of the semiconductor device array 100 shown in FIG. 1A taken along section line B-B′, according to an embodiment of the disclosure. Like numerals in FIGS. 1A, 1B and 1C refer to like features. For simplicity, the first 110 and second 114 contact pillars and the interlayer dielectric layer 136 are not shown in this cross-section. Referring to FIG. 1C, a well contact region 112 may be arranged in the well region 106 in the epitaxial layer 120. The well contact region 112 may be adjacent to the source region 108.

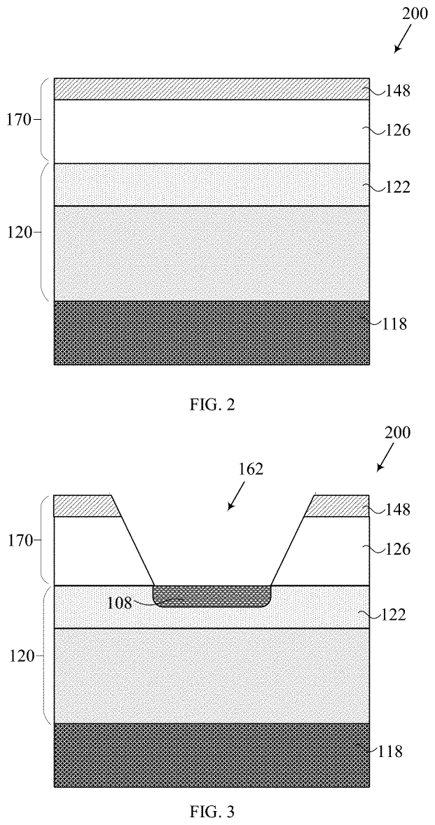

FIGS. 2 to 12 illustrate a process flow for fabricating a semiconductor device 200 shown in FIG. 1B, according to an embodiment of the disclosure. FIG. 2 shows a partially completed semiconductor device 200 with a substrate 118, an epitaxial layer 120 and a hard mask layer 170, according to an embodiment of the disclosure. Referring to FIG. 2, a substrate 118 and an epitaxial layer 120 over a first surface of the substrate 118 may be provided. The substrate 118 and the epitaxial layer 120 may be made of a wide bandgap semiconductor material. An upper portion 122 of the epitaxial layer 120 may be doped n-type to provide a first conductivity type. The doping may be by nitrogen doping or any other suitable n-type dopants. A field dielectric layer 126 may be deposited over the epitaxial layer 120. A sacrificial dielectric layer 148 may be deposited over the field dielectric layer 126. The field 126 and sacrificial 148 dielectric layers may provide a hard mask layer 170. In one embodiment, the field dielectric layer 126 may be made of silicon dioxide (SiO₂) and the sacrificial dielectric layer 148 may be made of silicon nitride (Si₃N₄). The deposition of the field 126 and sacrificial 148 dielectric layers may be by chemical vapor deposition (CVD), physical vapor deposition (PVD), atomic layer deposition (ALD) or any other suitable deposition processes.

FIG. 3 shows a partially completed semiconductor device 200 after formation of an opening 162 in the hard mask layer 170 and a source region 108, according to an embodiment of the disclosure. The patterning of the hard mask layer 170 to form the opening 162 may be by a conventional photolithography process followed by a wet or dry etch process. The conventional photolithography process may include depositing a layer of photoresist material over the hard mask layer 170 followed by exposure and developing to provide a photoresist pattern. A wet or dry etch process may be used to form an opening in the field 126 and sacrificial 148 dielectric layers by removing portions not covered by the photoresist pattern. The opening 162 may expose an upper portion 122 of the epitaxial layer 120. A source region 108 having a first conductivity type may be formed in the exposed upper portion 122 of the epitaxial layer 120. The formation of the source region 108 may be by implanting nitrogen (N), phosphorus (P) or any other suitable dopant through the opening 162 in the hard mask layer 170 thereby forming the source region 108. An activation anneal may be performed after the implantation process. Although not shown, the well contact region 112 may be formed after the formation of the source region 108 by implanting a portion of the epitaxial layer 120 adjacent to the source region 108 with aluminum (Al), boron (B), beryllium (Be), gallium (Ga) or any other suitable dopant followed by an activation anneal to provide a well contact region 112 having a second conductivity type.

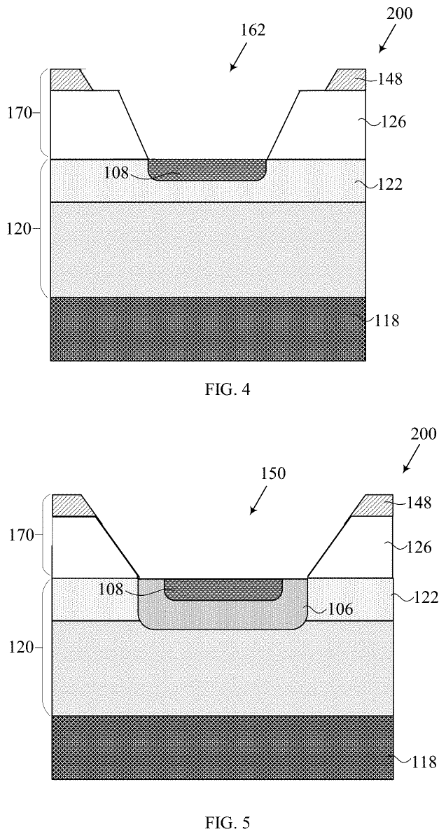

FIG. 4 shows a partially completed semiconductor device 200 after patterning of the hard mask layer 170, according to an embodiment of the disclosure. Referring to FIG. 4, the sacrificial dielectric layer 148 is further patterned by a wet etch process using hot phosphoric acid or any other suitable process to leave behind a portion of the sacrificial dielectric layer 148 over the field dielectric layer 126. The patterning process may cause a portion of the sacrificial dielectric layer adjacent to the circumference of the opening 162 to be removed, thereby exposing a portion of the field dielectric layer 126.

FIG. 5 shows a partially completed semiconductor device 200 after formation of an opening 150 in the hard mask layer 170 and a well region 106, according to an embodiment of the disclosure. Referring to FIG. 5, an exposed portion of the field dielectric layer 126 that is not covered by the sacrificial dielectric layer 148 may be removed by a wet or dry etch process to form the opening 150 in the field dielectric layer 126. The opening 150 may expose the source region 108 and a portion of the epitaxial layer 120 laterally adjacent to the source region 108. The exposed portion of the epitaxial layer 120 may be doped by a self-aligned implantation process to form a well region 106 having a second conductivity type. A portion of the epitaxial layer 120 under the source region 108 may also be doped by the same self-aligned implantation process to form a lower portion of the well region 106. The well region 106 may be laterally adjacent to a first side of the source region 108 and a second side of the source region 108 opposite to the first side. The well region 106 may also surround a bottom portion of the source region 108. In one embodiment, the doping may include implanting aluminum, boron, beryllium, gallium or any other suitable dopant followed by an activation annealing. In one embodiment, the source region 108 may be more heavily doped compared to the well region 106.

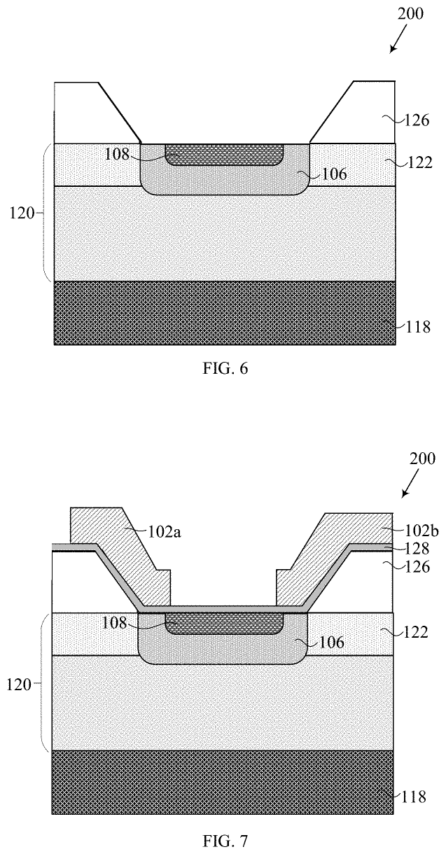

FIG. 6 shows a partially completed semiconductor device 200 after removal of a portion of the sacrificial dielectric layer 148, according to an embodiment of the disclosure. The removal may be by a wet or dry etch process. The removal process leaves behind the field dielectric layer 126 over the epitaxial layer 120 adjacent to the well region 106.

FIG. 7 shows a partially completed semiconductor device 200 after formation of a gate dielectric layer 128 and gate electrode layers 102a and 102b, according to an embodiment of the disclosure. Referring to FIG. 7, in one embodiment, the formation of the gate dielectric layer 128 may include depositing a suitable dielectric layer, for example silicon dioxide (SiO₂) or any other suitable dielectric material over a top surface of the source region 108, the well region 106 and the field dielectric layer 126 to thereby form the gate dielectric layer 128. The deposition process may be by atomic layer deposition (ALD), physical vapor deposition (PVD), chemical vapor deposition (CVD) or any other suitable deposition processes. In an alternative embodiment, the formation of the gate dielectric layer 128 may include growing a layer of suitable dielectric material, for example silicon dioxide or any other suitable dielectric material over a top surface of the source region 108, the well region 106 and the field dielectric layer 126 by thermal oxidation or any other suitable processes to thereby form the gate dielectric layer 128. The formation of the gate electrode layers 102a and 102b may include depositing a doped layer of polysilicon or any other suitable conductive material over the gate dielectric material layer 128. The deposition process may be by atomic layer deposition (ALD), physical vapor deposition (PVD), chemical vapor deposition (CVD) or any other suitable deposition processes. The doped polysilicon layer may be patterned by a conventional photolithography process followed by a wet or dry etch to leave behind a layer of doped polysilicon over the gate dielectric layer 128, the well region 106 and the field dielectric layer 126 to thereby form the gate electrode layers 102a and 102b. In one embodiment, the doped polysilicon layer may be n-doped.

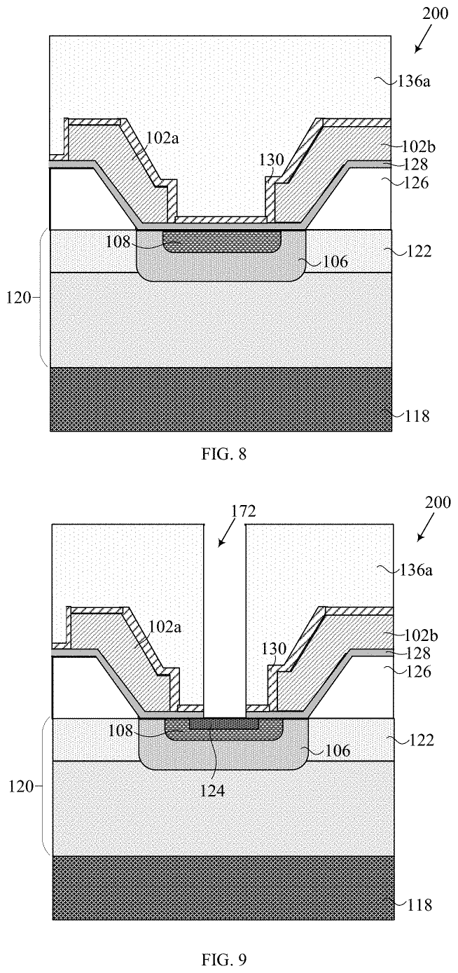

FIG. 8 shows a partially completed semiconductor device 200 after formation of spacer structure 130 and an interlayer dielectric (ILD) layer 136a, according to an embodiment of the disclosure. The formation of the spacer structure 130 may include depositing a layer of suitable dielectric material, for example silicon nitride (Si₃N₄) or any other suitable dielectric material over the gate electrode layers 102a and 102b and the gate dielectric layer 128. The formation of the interlayer dielectric (ILD) layer 136a may include depositing a layer of suitable dielectric material, for example silicon dioxide, high density plasma (HDP) undoped silicate glass (USG), tetraethyl orthosilicate (TEOS) or any other suitable dielectric material over the spacer structure 130 thereby forming the interlayer dielectric layer 136a. The deposition processes for the spacer structure 130 and the interlayer dielectric layer 136a may be by atomic layer deposition (ALD), physical vapor deposition (PVD), chemical vapor deposition (CVD) or any other suitable deposition processes. Although not shown, the interlayer dielectric layer 136a may also be formed over the well contact region 112.

FIG. 9 shows a partially completed semiconductor device 200 after formation of an opening 172 in the interlayer dielectric layer 136a, the spacer structure 130 and the gate dielectric layer 128. The opening 172 may be formed by a patterning process such as a conventional photolithography process followed by a wet or dry etch process. The patterning process may remove a portion of the gate dielectric layer 128 and a portion of the spacer structure 130 over a center portion of the source region 108, thereby exposing a center portion of the source region 108. A layer of suitable metal, for example titanium (Ti) or any other suitable metal may be deposited over the exposed portion of the source region 108 and annealed to thereby form a silicide layer 124 over the source region 108. The deposition process may be by physical vapor deposition (PVD), chemical vapor deposition (CVD) or any other suitable deposition processes.

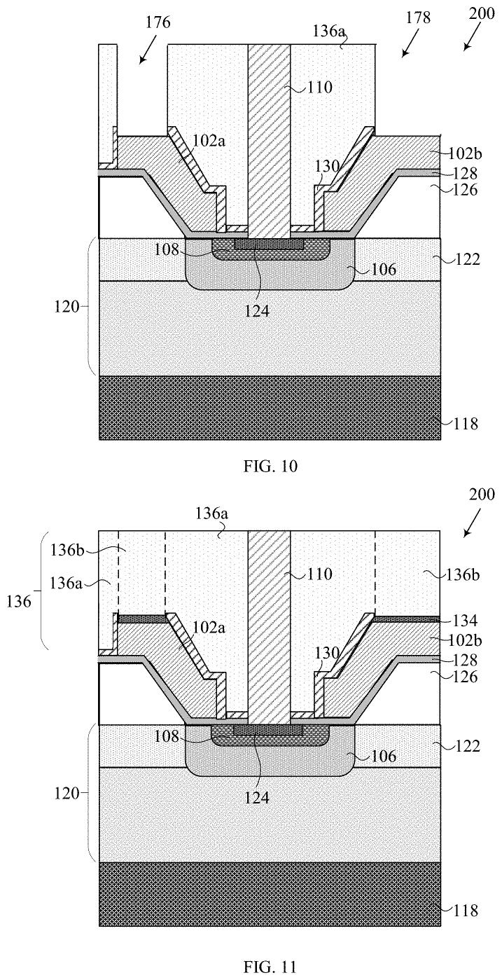

FIG. 10 shows a partially completed semiconductor device 200 after formation of a first contact pillar 110 and openings 176 and 178, according to an embodiment of the disclosure. The formation of the first contact pillar 110 may include depositing a layer of suitable metal, for example tungsten (W) or any other suitable metal in the opening 172 in the interlayer dielectric layer 136a over the silicide layer 124. The deposition process may be by physical vapor deposition (PVD), chemical vapor deposition (CVD) or any other suitable deposition processes. A suitable planarization process, for example chemical mechanical planarization (CMP) may be used to remove the tungsten layer from a top surface of the interlayer dielectric layer 136a leaving behind another portion of tungsten layer in the opening 172 in the interlayer dielectric layer 136a thereby forming the first contact pillar 110. The planarization process may also remove a layer of unreacted titanium from the silicidation process shown in FIG. 9. Although not shown, the formation of a second contact pillar 114 over a well contact region 112 may be formed in a similar manner as the formation of the first contact pillar 110. The formation of the openings 176 and 178 in the interlayer dielectric layer 136a may include patterning the interlayer dielectric layer 136a and the spacer structure 130 by a conventional photolithography process and a wet or dry etch process to thereby form the openings 176 and 178. The patterning process may remove portions of the spacer structure 130 from a top surface of the gate electrode layers 102a and 102b and leave behind a portion of the spacer structure 130 over a side surface of the gate electrode layers 102a and 102b. The openings 176 and 178 may expose a portion of a top surface of the gate electrode layers 102a and 102b over the field dielectric layer 126.

FIG. 11 shows a partially completed semiconductor device 200 after formation of a silicide layer 134 and an interlayer dielectric (ILD) layer 136b, according to an embodiment of the disclosure. The formation of the silicide layer 134 may include depositing a layer of suitable metal, for example nickel or cobalt or any other suitable metal over the exposed portion of the gate electrode layers 102a and 102b. An annealing process may thereby form the silicide layer 134 over the top surface of the gate electrode layers 102a and 102b. A layer of unreacted nickel may be removed after the silicidation process. A layer of suitable dielectric material, for example silicon dioxide, high density plasma (HDP) undoped silicate glass (USG), tetraethyl orthosilicate (TEOS) or any other suitable dielectric material may be deposited in the openings 176 and 178 to thereby form the interlayer dielectric layer 136b. In one embodiment, the interlayer dielectric layers 136a and 136b may be made of the same dielectric material. In another embodiment, the interlayer dielectric layers 136a and 136b may be made of different dielectric materials. The interlayer dielectric layers 136a and 136b may be collectively referred to as interlayer dielectric layer 136.

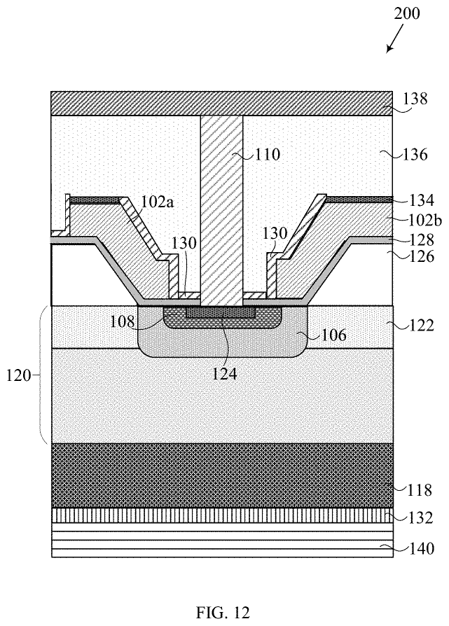

FIG. 12 shows a semiconductor device 200 after formation of a drain region 132, a drain contact 140 and a metallization layer 138, according to an embodiment of the disclosure. The formation of the drain region 132 may include deposition of a suitable metal, for example titanium or any other suitable metal over a second surface of the substrate 118 followed by low temperature annealing such as laser anneal to form a metal silicide to thereby form the drain region 132. Although not shown, prior to the formation of the drain region 132, a second interlayer dielectric layer may be formed over a top surface of the first interlayer dielectric layer 136 and the first contact pillar 110 to protect the first contact pillar 110 during the silicidation process. The drain contact 140 may be formed over the drain region 132. The formation of the drain contact 140 may include depositing a layer of suitable metal, for example titanium, nickel, silver (Ag), cobalt (Co), platinum (Pt), palladium (Pd), any other metal or its combinations over the drain region 132 to thereby form the drain contact 140. The deposition process may be by physical vapor deposition (PVD), chemical vapor deposition (CVD) or any other suitable deposition processes. The second interlayer dielectric layer may be removed from the top surface of the first interlayer dielectric layer 136 and the first contact pillar 110 after the formation of the drain contact 140. The removal process may be by a wet etch, dry etch or chemical mechanical planarization process. The removal process may expose a top surface of the first contact pillar 110. Although not shown, a trench opening to the silicide layer 134 over the gate electrode layer 102a and 102b may be formed. A contact pillar may be formed in the trench opening to contact the silicide layer 134. A layer of suitable metal, for example titanium (Ti)/Aluminum (Al)/Titanium (Ti) or any other suitable metal may be deposited over the first interlayer dielectric layer 136 and the first contact pillar 110 by electroplating, physical vapor deposition (PVD), chemical vapor deposition (CVD) or any other suitable deposition processes to thereby form the metallization layer 138. Although not shown, the metallization layer 138 may also be formed over the second contact pillar 114.

The terms “first”, “second”, “third”, and the like in the description and in the claims, if any, are used for distinguishing between similar elements and not necessarily for describing a particular sequential or chronological order. It is to be understood that the terms so used are interchangeable under appropriate circumstances such that the embodiments of the device described herein are, for example, capable of operation in sequences other than those illustrated or otherwise described herein. The terms “left”, “right”, “front”, “back”, “top”, “bottom”, “over”, “under”, and the like in the description and in the claims, if any, are used for descriptive purposes and not necessarily for describing permanent relative positions. It is to be understood that the terms so used are interchangeable under appropriate circumstances such that the embodiments of the device described herein are, for example, capable of operation in other orientations than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device.

While several exemplary embodiments have been presented in the above detailed description of the device, it should be appreciated that number of variations exist. It should further be appreciated that the embodiments are only examples, and are not intended to limit the scope, applicability, dimensions, or configuration of the devices in any way. Rather, the above detailed description will provide those skilled in the art with a convenient road map for implementing an exemplary embodiment of the devices, it being understood that various changes may be made in the function and arrangement of elements and method of fabrication described in an exemplary embodiment without departing from the scope of this disclosure as set forth in the appended claims.

What is claimed:

1. A structure comprising:
a substrate having a wide bandgap semiconductor material;
an epitaxial layer over a first surface of the substrate;
a source region having a first conductivity type in the epitaxial layer;
a well region having a second conductivity type laterally adjacent to the source region, wherein the second conductivity type is different from the first conductivity type;
a gate dielectric layer over the well region; and
a field dielectric layer over the epitaxial layer adjacent to the well region.

2. The structure of claim 1, wherein the well region surrounds the source region.

3. The structure of claim 1, wherein the gate dielectric layer is thinner than the field dielectric layer.

4. The structure of claim 1 further comprising:
a gate electrode over the gate dielectric layer and the field dielectric layer.

5. The structure of claim 4 further comprising:
an interlayer dielectric (ILD) layer over the source region and the gate electrode.

6. The structure of claim 5 further comprising:
a first contact pillar over the source region, wherein the first contact pillar is in the interlayer dielectric layer.

7. The structure of claim 6 further comprising:
a well contact region having a second conductivity type in the well region.

8. The structure of claim 7 further comprising:
a second contact pillar over the well contact region.

9. The structure of claim 8 further comprising:
a metallization layer over the first contact pillar and the second contact pillar.

10. The structure of claim 1, wherein the wide bandgap semiconductor material includes silicon carbide (SiC).

11. The structure of claim 1 further comprising:
a drain region over a second surface of the substrate opposite to the first surface.

12. A structure comprising:
a substrate having a wide bandgap semiconductor material;
an epitaxial layer over a first surface of the substrate, wherein the epitaxial layer includes the same wide bandgap semiconductor material as the substrate;
a source region having a first conductivity type in an upper portion of the epitaxial layer;
a well region having a second conductivity type laterally adjacent to the source region, wherein the second conductivity type is different from the first conductivity type;
a gate dielectric layer over the well region; and
a field dielectric layer over the epitaxial layer adjacent to the well region.

13. The structure of claim 12, wherein the well region surrounds the source region.

14. The structure of claim 12, wherein the gate dielectric layer is thinner than the field dielectric layer.

15. The structure of claim 12 further comprising:
a well contact region having a second conductivity type in the well region.

16. The structure of 15, wherein the well contact region is laterally adjacent to the source region.

17. The structure of claim 12 further comprising a gate electrode layer over the well region.

18. The structure of claim 17, wherein the gate electrode layer partially overlaps the source region.

19. The structure of claim 12, wherein the well region is laterally adjacent to a first side of the source region and a second side of the source region opposite to the first side.

20. A method of fabricating a semiconductor structure comprising:
providing a substrate having a wide bandgap semiconductor material;
forming an epitaxial layer over a first surface of the substrate;
forming a source region having a first conductivity type in the epitaxial layer;
forming a well region having a second conductivity type laterally adjacent to the source region, wherein the second conductivity type is different from the first conductivity type;
forming a field dielectric layer over the epitaxial layer adjacent to the well region; and
forming a gate dielectric layer over the well region.
